(19) United States
(12) Patent Application Publication
(10) Pub. No.: US 2024/0298549 A1
(43) Pub. Date: Sep. 5, 2024

(54) MAGNETIC DEVICE AND MAGNETIC STORAGE DEVICE

(71) Applicant: Kioxia Corporation, Tokyo (JP)

(72) Inventors: Rina NOMOTO, Bunkyo Tokyo (JP); Hideyuki SUGIYAMA, Kawasaki Kanagawa (JP); Daisuke WATANABE, Yokkaichi Mie (JP); Bao NGUYEN VIET, Yokohama Kanagawa (JP); Youngmin EEH, Kawagoe Saitama (JP); Masaru TOKO, Kodaira Tokyo (JP); Taiga ISODA, Yokohama Kanagawa (JP)

(21) Appl. No.: 18/592,306

(22) Filed: Feb. 29, 2024

(30) Foreign Application Priority Data
Mar. 1, 2023 (JP) 2023-030853

(51) Int. Cl. H10N 50/85; H10B 61/00; H10N 50/20

(52) U.S. Cl. CPC H10N 50/85; H10B 61/10; H10N 50/20

(57) ABSTRACT

A magnetic device includes a first magnetic layer, a second magnetic layer, and a nonmagnetic layer between the first and second magnetic layers and including: a first layer in contact with the first magnetic layer and including a magnesium oxide, a second layer in contact with the second magnetic layer and including a magnesium oxide, and a third layer between the first and second layers and including a scandium nitride.

### CROSS-REFERENCE TO RELATED APPLICATION(S)

This application is based upon and claims the benefit of priority from Japanese Patent Application No. 2023-030853, filed Mar. 1, 2023, the entire contents of which are incorporated herein by reference.

### FIELD

Embodiments described herein relate generally to a magnetic device and a magnetic storage device.

### BACKGROUND

In a magnetic random access memory (MRAM) which has been known as a nonvolatile memory, write and read operations are performed using a magnetic tunnel junction (MTJ) element. The MTJ element generally has a structure obtained by stacking three layers, i.e., a magnetic layer as a storage layer, a tunnel barrier layer, and a magnetic layer as a reference layer. In the MTJ element, a magnesium oxide (MgO) layer is generally used as the tunnel barrier layer, but a dielectric breakdown voltage of the MgO layer is insufficient and thus dielectric breakdown may occur during write operation. Therefore, it is required to improve characteristics of the MTJ element by increasing the dielectric breakdown voltage of the tunnel barrier layer.

### BRIEF DESCRIPTION OF THE DRAWINGS

FIG. 1 is a cross-sectional diagram illustrating a magnetic device according to an embodiment.

FIG. 2 is a diagram illustrating a magnetic storage device having a cross-point structure using the magnetic device.

FIG. 3 is an enlarged cross-sectional diagram illustrating a portion of the magnetic devices.

FIG. 4 is a diagram illustrating an absolute value of an enthalpy of formation (ΔH) of various metal nitrides.

FIG. 5 is a diagram illustrating a relationship between a resistance area product (RA) and a tunnel magnetoresistance (TMR) ratio of an MTJ element in which a three-layer stacked structure of MgO/ScN/MgO is applied to a tunnel barrier layer.

FIG. 6 is a diagram illustrating a relationship between a composition range of a third nonmagnetic layer and a film thickness in the tunnel barrier layer of the magnetic device.

### DETAILED DESCRIPTION

Embodiments provide a magnetic device and a magnetic storage device, capable of improving characteristics thereof by increasing dielectric breakdown voltage of a tunnel barrier layer.

In general, according to one embodiment, a magnetic device includes a first magnetic layer, a second magnetic layer, and a nonmagnetic layer between the first and second magnetic layers and including: a first layer in contact with the first magnetic layer and including a magnesium oxide, a second layer in contact with the second magnetic layer and including a magnesium oxide, and a third layer between the first and second layers and including a scandium nitride.

Hereinafter, embodiments of a magnetic device and a magnetic storage device will be described with reference to the drawings. In each embodiment presented below, substantially the same components are denoted by the same reference signs, and a description thereof is sometimes partially omitted. The drawings are drawn schematically or conceptually, and a relationship between a thickness and a width of each component and a ratio between sizes of the components are not necessarily exactly the same as in an actual device.

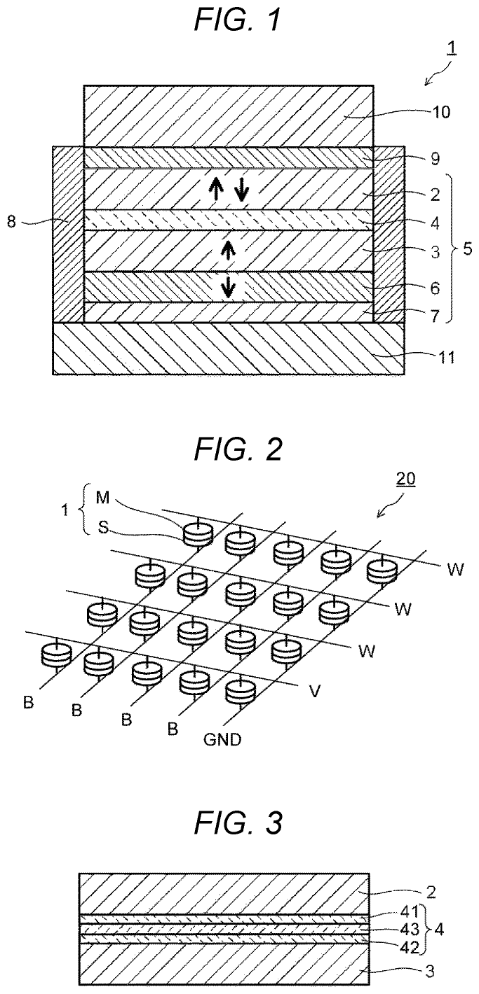

FIG. 1 illustrates a configuration of a magnetic device 1 according to an embodiment. The magnetic device 1 illustrated in FIG. 1 includes a stack 5 including a first magnetic layer 2 as a storage layer, a second magnetic layer 3 as a reference layer, and a nonmagnetic layer 4 as a tunnel barrier layer sandwiched between the first magnetic layer 2 and the second magnetic layer 3. The stack 5 further includes a third magnetic layer 6 as a shift cancellation layer disposed below the second magnetic layer 3, and a buffer layer 7 functioned as a seed layer and the like disposed further below a third magnetic layer 6. A sidewall layer 8 is disposed around the stack 5 to cover a side wall thereof. The stack 5 illustrated in FIG. 1 forms, for example, an MTJ element, but it is not limited thereto.

When applying the magnetic device 1 to the MTJ element, the second magnetic layer 3 is a reference layer, which is sometimes referred to as a magnetization pinned layer or a pinned layer, where a spin direction (i.e., a magnetization direction) is fixed. A magnetization direction of the second magnetic layer 3 is fixed by the third magnetic layer 6 as the shift cancellation layer. For example, a CoFeB/Mo/Co/Ir stacked film, a CoFeB/Mo/Co/Ru stacked film, or the like is used as the second magnetic layer 3. A magnetic material, such as a [Co/Pt] superlattice or a [Co/Ir] superlattice, is used as the third magnetic layer 6. In the stacked film forming the reference layer 3, the Ir layer or Ru layer realize antiparallel coupling with the shift cancellation layers 6. Consequently, magnetization of the magnetic layer, such as the CoFeB layer, in the stacked film forming the reference layer 3 is fixed.

On the second magnetic layer 3 as the reference layer, the first magnetic layer 2 functioning as a storage layer (i.e., a free layer) is disposed via the nonmagnetic layer 4 functioned as the tunnel barrier layer. The first magnetic layer 2 functions as a storage layer where the spin direction (i.e., the magnetization direction) changes in accordance with storage contents. A magnetic material, such as a Co-based alloy such as CoFeB, CoPt, or CoPtCr, or a [Co/Pt] superlattice, is used as the first magnetic layer 2.

A thickness of each of the first magnetic layer 2 and the second magnetic layer 3 (i.e., the CoFeB layer in the stacked film) is not particularly limited, but it is preferably, for example, 0.2 nm or more and 5 nm or less. A thickness of the nonmagnetic layer 4 is preferably, for example, 0.5 nm or more and 2.5 nm or less. Detailed configuration and composite material of the nonmagnetic layer 4 as the tunnel barrier layer will be described later. As the buffer layer 7 disposed below the third magnetic layer 6, a seed layer, such as Ru, Ta, or CoFeB—Mo, is applied. An insulator, such as a silicon oxide (SiOx), a zirconium oxide (ZrOx), an aluminum oxide (AlOx), an aluminum nitride (AlNx), or a silicon nitride (SiNx), is applied to a composite material of the sidewall layer 8. On the stack 5, a cap layer 9 containing Ta, Pt, Ru, or the like is disposed. A wiring layer 10 is disposed on the cap layer 9. W, Mo, Ta, or an alloy containing these materials are used for the wiring layer 10, but it is not particularly limited thereto.

Below the stack 5 as the MTJ element, a switching layer 11 electrically connected to the MTJ element 5 is disposed. The switching layer 11 has a function (hereinafter referred to as a switching function) of switching ON/OFF of a current supplied to the MTJ element 5. The switching layer 11 has electrical characteristics that rapidly change from an OFF state with a high resistance value to an ON state with a low resistance value when a voltage higher than a threshold value (Vth) is applied. More specifically, a material (hereinafter referred to as a switching material) forming the switching layer 11 has electrical characteristics in which it is in the OFF state with the high resistance value when the voltage to be applied is lower than the threshold value (Vth), and it rapidly changes from the OFF state with the high resistance value to the ON state with the low resistance value when the voltage becomes higher than the threshold value (Vth). Such a change in the resistance value of the switching layer 11 based on the applied voltage occurs reversibly and rapidly.

The switching material contains, for example, a material containing at least one chalcogen element selected from the group including tellurium (Te), selenium (Se), and sulfur (S). Such a switching material may contain chalcogenide, which is a compound containing a chalcogen element. The material containing the chalcogen element may contain at least one element selected from the group including Al, Ga, In, Si, Ge, Sn, As, P, Sb, and Bi. The material containing the chalcogen element may contain at least one element selected from the group including N, O, C, and B. GeSbTe, GeTe, SbTe, SiTe, AlTeN, GeAsSe, or the like may be cited as examples of the switching material. The switching material may be a material contain no chalcogen element. The switching material may be a material containing additive elements such as antimony (Sb), germanium (Ge), arsenic (As), and bismuth (Bi), e.g., a material in which the additive element is applied to an oxide or a nitride. ZrOx, AlOx, SiOx, TaOx, HfOx, or the like may be cited as such a switching material. The switching material may be a material in which the above-described additive element or Te, Se, or the like is applied to the oxides. The switching layer 11 may have an amorphous structure.

As illustrated in FIG. 2, the magnetic device 1 forming an MRAM and the like is disposed at each of intersection points between a plurality of bit lines BL and a plurality of word lines WL, and functions as a memory cell. As illustrated in FIG. 2, the magnetic device 1 electrically connected to the bit line BL and the word line WL as the memory cell is disposed at each of the intersection points formed respectively between the plurality of bit lines BL and the word lines WL, and thereby a magnetic storage device 20 is formed. The magnetic storage device 20 illustrated in FIG. 2 includes wirings that include a plurality of bit lines BL and a plurality of word lines WL, and a plurality of magnetic devices 1, each disposed at each intersection point therebetween and electrically connected to each bit line BL and each word line WL. In FIG. 2, the reference sign M denotes the stack 5 functioning as the MTJ element illustrated in FIG. 1, and the reference sign S denotes the switching layer 11 disposed below the stack 5.

In the magnetic device 1 illustrated in FIG. 1, the nonmagnetic layer 4 as the tunnel barrier layer, as illustrated in FIG. 3, has a three-layer stacked structure including a first nonmagnetic layer 41 in contact with the first magnetic layer 2 as the storage layer, a second nonmagnetic layer 42 in contact with the second magnetic layer 3, and a third nonmagnetic layer 43 disposed between the first nonmagnetic layer 41 and the second nonmagnetic layer 42. A specific configuration and composite materials of the nonmagnetic layer 4 having such a three-layer stacked structure will be described in detail later.

When only a magnesium oxide (MgO) layer generally used as such a tunnel barrier layer is applied to the nonmagnetic layer 4, for example, dielectric breakdown voltage can be secured due to an element size where a half pitch exceeds 14 nm, but it is difficult to pass dielectric breakdown voltage conditions due to an element size where the half pitch is 14 nm or less. Namely, when the element size where the half pitch is 14 nm or less, it is necessary to reduce a resistance area product (a product of a resistance value and an area: RA) by thinning the MgO layer, and the dielectric breakdown voltage cannot be satisfied with such a thinned MgO layer.

Moreover, for example, when MgO generally used as the tunnel barrier layer is applied to the first nonmagnetic layer 41 and the second nonmagnetic layer 42 and an oxide of a metallic element except for Mg or the like is applied to the third nonmagnetic layer 43, it may be possible to make the nonmagnetic layer thicker without increasing resistance. In this case, it is considered possible to increase the dielectric breakdown voltage while satisfying basic characteristics of the MTJ element. However, there is a risk that the metallic element may be concentrated to an interface of the tunnel barrier layer due to diffusion by annealing or other processes during film formation. This makes it difficult to fabricate the targeted three-layer stacked structure.

From such a reason, when the three-layer stacked structure including the first nonmagnetic layer 41, the second nonmagnetic layer 42, and the third nonmagnetic layer 43 is applied to the nonmagnetic layer 4, a material containing MgO (herein referred to as a composite material B) is used for the first nonmagnetic layer 41 and the second nonmagnetic layer 42 which are respectively in contact with the first magnetic layer 2 and the second magnetic layer 3 in order to increase a TMR ratio. For a composite material A of the intermediate third nonmagnetic layer 43, it is preferable to use a material that does not cause element diffusion between the first nonmagnetic layer 41 and the second nonmagnetic layer 42 and do not increase resistance, and has a barrier lower than that of MgO, i.e., a bandgap is smaller than that of MgO.

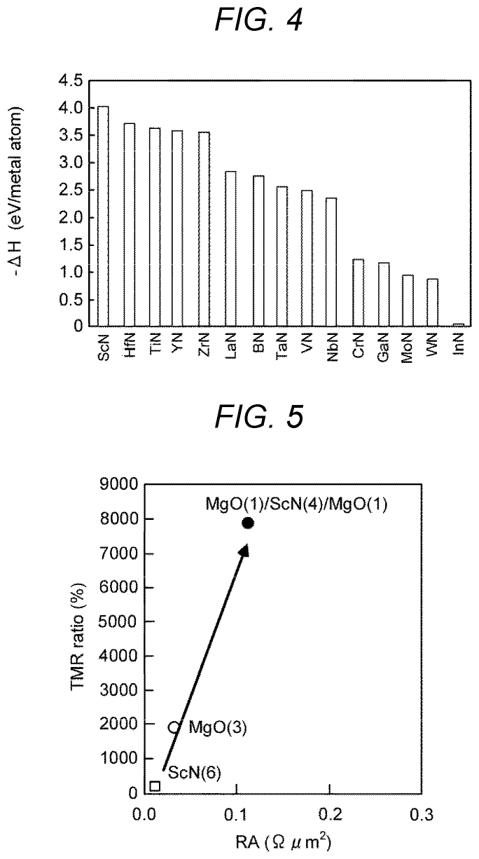

When a material with a small enthalpy of formation of oxides or nitrides is used as the composite material A of the intermediate third nonmagnetic layer 43, a diffusion barrier tends to increase and diffusion becomes difficult to occur. Furthermore, considering that a nitride is applied to the composite material A and CoFeB is used as at least a portion of the first magnetic layer 2 and the second magnetic layer 3, a nitride with a smaller enthalpy of formation (ΔH) than a boron nitride (BN) is effective in order to reduce formation of high-resistance BN. The enthalpy of formation (ΔH) of BN is −2.74 (eV/B atom). FIG. 4 illustrates enthalpies of formation (ΔH) of various metal nitrides at absolute zero. The vertical axis indicates −ΔH. As illustrated in FIG. 4, since a scandium nitride (ScN), a hafnium nitride (HfN), a titanium nitride (TiN), an yttrium nitride (YN), a zirconium nitride (ZrN), and a lanthanum nitride (LaN) all have smaller enthalpies of formation (ΔH) than that of BN, when using the third nonmagnetic layer 43 as the composite material A, it is possible to inhibit diffusion due to annealing or other processes during film formation. Therefore, the nonmagnetic layer 4 having the three-layer stacked structure can be formed with sufficient accuracy by applying the above-described material A to the third nonmagnetic layer 43.

In one embodiment, the three-layer stacked structure forms a magnetic memory that includes a tunnel barrier with an MgO/ScN/MgO tri-layer, i.e., an MgO layer 1, an MgO layer 2, and an ScN layer therebetween. The MgO layer 1 is closer to the substrate than the MgO layer 2. The MgO layer 1 is thick enough to be highly oriented crystal such that a large tunnel current flows through the crystalized MgO/ScN/MgO tri-layer. The MgO layer 2 is thin enough to have low normalized tunnel resistance RA through the MgO/ScN/MgO tri-layer.

At the tunnel barrier, the MgO layer 1 can be thicker, for example, by 0.2 nm or more than the MgO layer 2, and the MgO layer 2 can be thinner than 0.3 nm. The tunnel barrier may comprise an MgO/ScON/MgO tri-layer including scandium oxide and nitride ScON with NaCl type crystal structure and the MgO layer 1 having a thickness greater than that of the MgO layer 2.

The above-described materials A, such as ScN, HfN, TiN, YN, ZrN, and LaN, each take a rock salt type crystal structure. Since MgO also takes rock salt type crystal structure, a three-layer stacked structure of rock salt type MgO/a material A such as rock salt type ScN or the like/rock salt type MgO allows each layer to be stacked with sufficient lattice matching property. Therefore, each layer of the rock salt type MgO/the material A such as rock salt type ScN or the like/the rock salt type MgO can be formed with sufficient crystallinity. Furthermore, since ScN has a smaller barrier than that of MgO, the three-layer stacked structure of MgO/ScN/MgO allows the nonmagnetic layer 4 as the tunnel barrier layer to be thicker while maintaining a high TMR ratio. This makes it possible to increase the dielectric breakdown voltage of the nonmagnetic layer 4 as the tunnel barrier layer.

FIG. 5 illustrates a relationship between the resistance area product (RA) and the TMR ratio, with regard to MTJ elements of comparative examples 1 and 2 in which ScN (6 atomic layers) and MgO (3 atomic layers) are respectively applied to the nonmagnetic layer 4 as the tunnel barrier layer, and an MTJ element according to an embodiment 1 in which a stacked film of MgO (1 atomic layer)/ScN (4 atomic layers)/MgO (1 atomic layer) is applied to the nonmagnetic layer 4. As illustrated in FIG. 5, the embodiment 1 (i.e., the MTJ element in which the stacked film of MgO (1 atomic layer)/ScN (4 atomic layers)/MgO (1 atomic layer) is applied to the nonmagnetic material) achieves a 2.2 times thicker film where RA is 0.11 Ωμm2 or less, and a dielectric breakdown voltage based thereon, compared with the comparative example 2 (i.e., the MTJ element in which MgO (3 atomic layers) is applied to the nonmagnetic material). In addition thereto, the MTJ element according to the embodiment 1 achieves a high TMR ratio by disposing the ScN layer (the third nonmagnetic layer 43) between the MgO layers (the first and second nonmagnetic layers 41 and 42).

The above-described improvement effect of the dielectric breakdown voltage is not limited to the three-layer stacked structure of MgO/ScN/MgO. A similar effect can be realized by applying a third nonmagnetic layer 43 having a rock salt type crystal structure similar to ScN and containing at least one selected from the group including HfN, TiN, YN, a ZrN, and LaN having a smaller barrier than that of MgO, i.e., a smaller bandgap than that of MgO, to the three-layer stacked structure of the first nonmagnetic layer 41 containing MgO/the third nonmagnetic layer 43/the second nonmagnetic layer 42 containing MgO. Namely, the dielectric breakdown voltage can be improved by increasing the TMR ratio and increasing the thickness without increasing the electrical resistance.

Thus, the nonmagnetic layer 4 as the tunnel barrier layer according to the above-described embodiments includes the three-layer stacked structure in which the third nonmagnetic layer 43 containing at least one (i.e., the material A) selected from the group including ScN, HfN, TiN, YN, ZrN, and LaN is disposed between the first nonmagnetic layer 41 containing MgO and the second nonmagnetic layer 42 containing MgO. The first nonmagnetic layer 41 and the second nonmagnetic layer 42 are not limited to a single layer of MgO, and may contain a composite compound such as MgO, e.g., MgAlO, containing at least one selected from the group including aluminum (Al), zinc (Zn), gallium (Ga), argon (Ar), krypton (Kr), cobalt (Co), iron (Fe), platinum (Pt), and boron (B). The third nonmagnetic layer 43 is not limited to a single layer such as ScN and HfN, and may containing at least one selected from the group including a scandium oxide (ScO), a hafnium oxide (HfO), a titanium oxide (TiO), an yttrium oxide (YO), a zirconium oxide (ZrO), and a lanthanum oxide (LaO). Furthermore, it is preferable that at least any one of a concentration of these oxides in an interface of the third nonmagnetic layer 43 with the first nonmagnetic layer 41 and a concentration of the oxides concerned in an interface of the third nonmagnetic layer 43 with the second nonmagnetic layer 42 is higher than a concentration of the oxides concerned inside the third nonmagnetic layer 43. These can improve the adhesion between each layer. Moreover, the third nonmagnetic layer 43 may contain at least one selected from the group including argon (Ar), krypton (Kr), cobalt (Co), iron (Fe), platinum (Pt), and boron (B).

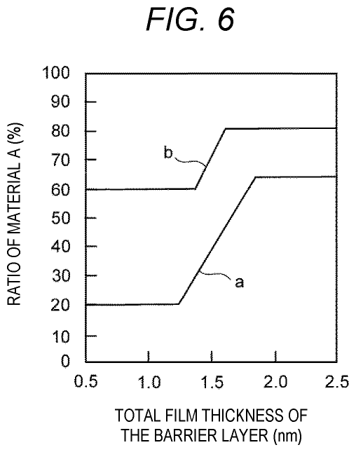

A total film thickness of the nonmagnetic layer 4 having the three-layer stacked structure of first nonmagnetic layer 41/the third nonmagnetic layer 43/the second nonmagnetic layer 42 is preferably within a range of 0.5 nm or more and 2.5 nm or less. FIG. 6 illustrates a preferable film thickness range of the third nonmagnetic layer 43 with respect to the total film thickness of the nonmagnetic layer 4 as the tunnel barrier layer in the three-layer stacked structure. In FIG. 6, the horizontal axis indicates the total film thickness of the barrier layer and the vertical axis indicates a composition ratio or a molar ratio of the material A in the entire barrier layer. Furthermore, the lower side line a is a lower limit value α of a composition ratio y of the material A and the upper line b is an upper limit value β of a composition ratio y of the material A, where y is the composition ratio (%) of the material A in the composite material of the first nonmagnetic layer 41, the second nonmagnetic layer 42, and the third nonmagnetic layer 43, and x is the total film thickness (nm) of the barrier layer.

In FIG. 6, the line a indicates that the lower limit value α of the composition ratio y is 20% when the film thickness x is 0.5≤x<1.25 (nm), the lower limit value α of the composition ratio y is α=74.2x−72.53(%) when the film thickness x is 1.25≤x<1.84 (nm), and the lower limit value α of the composition ratio y is 64% when the film thickness x is 1.84≤x (nm). The line b indicates that the upper limit value β of the composition ratio y is 60% when the film thickness x is 0.5≤x<1.37 (nm), the upper limit value β of the composition ratio y is β=87.5x−59.88(%) when the film thickness x is 1.37≤x<1.61 (nm), and the upper limit value β of the composition ratio y is 81% when the film thickness x is 1.61≤x (nm).

It is preferable that the third nonmagnetic layer 43 has a thickness where the composition ratio of the material A described above is within a range of the composition ratio y sandwiched between the line α (i.e., the lower limit value) and the line β (i.e., the upper limit value) in FIG. 6, where the total film thickness of the nonmagnetic layer 4 is within a range of 0.5 nm or more and 2.5 nm or less. It is more preferable that the third nonmagnetic layer 43 has a thickness where the composition ratio of the material A described above is within a range of the composition ratio y sandwiched between the line α and the line β in FIG. 6, where the total film thickness of the nonmagnetic layer 4 is within a range of 0.8 nm or more and 2.1 nm or less. By satisfying the composition range of the total film thickness and the range of the composition ratio y, it is possible to increase the TMR ratio of the magnetic device 1 as the MTJ element with more sufficient reproducibility and also to improve the dielectric breakdown voltage.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A magnetic device comprising:
a first magnetic layer;
a second magnetic layer; and
a nonmagnetic layer between the first and second magnetic layers and including:
a first layer in contact with the first magnetic layer and including a magnesium oxide,
a second layer in contact with the second magnetic layer and including a magnesium oxide, and
a third layer between the first and second layers and including a scandium nitride.

2. The magnetic device according to claim 1, further comprising:
a substrate, wherein
the first layer is closer to the substrate than the second layer, and
the first layer is thicker than the second layer.

3. The magnetic device according to claim 1, wherein the third layer further includes a scandium oxide.

4. The magnetic device according to claim 3, wherein a concentration of the scandium oxide at at least any one of an interface of the third layer with the first layer and an interface of the third layer with the second layer is higher than a concentration of the scandium oxide inside the third layer.

5. The magnetic device according to claim 1, wherein the third layer further includes at least one selected from the group consisting of argon, krypton, cobalt, iron, platinum, and boron.

6. The magnetic device according to claim 1, wherein at least one of the first and second layers includes at least one selected from the group consisting of aluminum, zinc, gallium, argon, krypton, cobalt, iron, platinum, and boron.

7. The magnetic device according to claim 1, wherein where x is a total thickness of the first, second, and third layers in nanometers, and y is a composition ratio of the scandium nitride in a composite material of the first, second, and third layers in percentages,
a lower limit value α of the composition ratio y is 20% when the total thickness x is 0.5≤x<1.25 (nm), the lower limit value α of the composition ratio y is α=74.2x−72.53(%) when the total thickness x is 1.25≤x<1.84 (nm), and the lower limit value α of the composition ratio y is 64% when the total thickness x is 1.84≤x≤2.5 (nm), and
an upper limit value β of the composition ratio y is 60% when the total thickness x is 0.5≤x<1.37 (nm), the upper limit value β of the composition ratio y is β=87.5x−59.88(%) when the total thickness x is 1.37≤x<1.61 (nm), and the upper limit value β of the composition ratio y is 81% when the total thickness x is 1.61≤x≤2.5 (nm).

8. The magnetic device according to claim 1, wherein a total thickness of the first, second, and third layers is within a range of 0.8 nm or more and 2.1 nm or less.

9. The magnetic device according to claim 1, wherein at least a portion of the first magnetic layer and at least a portion of the second magnetic layer include cobalt, iron, and boron.

10. A magnetic device comprising:
a first magnetic layer;
a second magnetic layer; and
a nonmagnetic layer between the first and second magnetic layers and including:
a first layer in contact with the first magnetic layer and including a magnesium oxide,
a second layer in contact with the second magnetic layer and including a magnesium oxide, and
a third layer between the first and second layers and including a nitride having a smaller bandgap than that of a magnesium oxide and a smaller enthalpy of formation than that of a boron nitride, wherein
the third layer includes at least one selected from the group consisting of a scandium nitride, a hafnium nitride, a titanium nitride, an yttrium nitride, a zirconium nitride, and a lanthanum nitride.

11. The magnetic device according to claim 10, wherein each of the first, second, and third layers includes a crystal having a rock salt structure.

12. The magnetic device according to claim 10, wherein the third layer further includes at least one oxide selected from the group consisting of a scandium oxide, a hafnium oxide, a titanium oxide, an yttrium oxide, a zirconium oxide, and a lanthanum oxide.

13. The magnetic device according to claim 12, wherein a concentration of the oxide at at least any one of an interface of the third layer with the first layer and an interface of the third layer with the second layer is higher than a concentration of the oxide inside the third layer.

14. The magnetic device according to claim 10, wherein the third layer further includes at least one selected from the group consisting of argon, krypton, cobalt, iron, platinum, and boron.

15. The magnetic device according to claim 10, wherein at least one of the first and second layers includes at least one selected from the group consisting of aluminum, zinc, gallium, argon, krypton, cobalt, iron, platinum, and boron.

16. The magnetic device according to claim 10, wherein where x is a total thickness of the first, second, and third layers in nanometers, and y is a composition ratio of the nitride in a composite material of the first, second, and third layers in percentages,
a lower limit value α of the composition ratio y is 20% when the total thickness x is 0.5≤x<1.25 (nm), the lower limit value α of the composition ratio y is α=74.2x−72.53(%) when the total thickness x is 1.25≤x<1.84 (nm), and the lower limit value α of the composition ratio y is 64% when the total thickness x is 1.84≤x≤2.5 (nm), and
an upper limit value β of the composition ratio y is 60% when the total thickness x is 0.5≤x<1.37 (nm), the upper limit value β of the composition ratio y is β=87.5x−59.88(%) when the total thickness x is 1.37≤x<1.61 (nm), and the upper limit value β of the composition ratio y is 81% when the total thickness x is 1.61≤x≤2.5 (nm).

17. The magnetic device according to claim 10, wherein a total thickness of the first, second, and third layers is within a range of 0.8 nm or more and 2.1 nm or less.

18. The magnetic device according to claim 10, wherein at least a portion of the first magnetic layer and at least a portion of the second magnetic layer include cobalt, iron, and boron.

19. A magnetic storage device comprising:
a plurality of first wirings extending along a first direction;
a plurality of second wirings extending along a second direction intersecting the first direction; and
a plurality of magnetic devices each electrically connected to a corresponding one of the first wirings and a corresponding one of the second wirings therebetween, wherein
each of the magnetic devices includes:
a first magnetic layer,
a second magnetic layer, and
a nonmagnetic layer between the first and second magnetic layers and including:
a first layer in contact with the first magnetic layer and including a magnesium oxide,
a second layer in contact with the second magnetic layer and including a magnesium oxide, and
a third layer between the first and second layers and including a scandium nitride.

20. The magnetic storage device according to claim 19, wherein the first and second magnetic layers and the nonmagnetic layer are stacked along a third direction intersecting the first and second directions.
